(19) United States
(12) Patent Application Publication
(10) Pub. No.: US 2005/0100668 A1
(43) Pub. Date: May 12, 2005

(54) Method for increasing the mobility of vapor-deposited pentacene

(76) Inventor: Jeffrey Scott Meth, Landenberg, PA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 10/949,867

(22) Filed: Sep. 24, 2004

Related U.S. Application Data
(60) Provisional application No. 60/505,533, filed on Sep. 24, 2003.

(51) Int. Cl. C23C 16/00

(52) U.S. Cl. 427/255.6

(57) ABSTRACT

This invention provides a method for increasing the charge-carrier mobility in vapor-deposited pentacene, resulting in improved semiconductor properties.

### FIELD OF THE INVENTION

This invention provides a method for increasing the charge-carrier mobility in vapor-deposited pentacene, resulting in improved semiconductor properties.

### TECHNICAL BACKGROUND OF THE INVENTION

This film transistor (TFT) arrays for flat-panel displays are typically fabricated using amorphous-silicon-on-glass technology. Emerging display applications, such as electronic paper or remotely-updateable posters, will require TFT arrays on flexible substrates fabricated over very large areas, features that are difficult to achieve with amorphous silicon devices. In addition, these new applications will only gain wide acceptance if they can be produced at significantly lower cost that current capital-intensive techniques allow. Consequently, there is significant interest in both the development of organic electronic materials and their incorporation into TFTs using low-cost fabrication techniques.

Aromatic compounds with extended pi-structures have been intensively studied for use as semiconductor materials in electronic devices, including TFTs. The properties of pentacene have made it as especially attractive organic semiconductor material, but some of its electronic properties, including the mobility of its charge-carriers, have proven difficult to control, or have been very sensitive to processing conditions and/or environmental factors.

It has recently been discovered that vapor deposition of pentacene on poly (hydroxystyrene) leads to the formation of a pentacene layer with larger domains and fewer grain boundaries. Although this morphology difference is understood to be responsible for improved mobility properties of pentacene that has been vapor-deposited on poly(hydroxystyrene), the reasons for the morphology differences have not yet been identified.

### SUMMARY OF THE INVENTION

This invention provides a method for forming pentacene films with high charge carrier mobilities comprising vapor-depositing pentacene onto films or substrates comprising polymers selected from the group consisting of poly(vinylpyridine) and poly(vinylnaphthalene).

The vapor-deposited films of pentacene are useful as the semiconductor component in the fabrication of TFTs.

### BRIEF DESCRIPTION OF THE FIGURE

FIG. 1 provides AFM images of pentacene on: poly(hydroxy stryrene), poly(vinyl pyridine); poly(vinyl naphthalene); poly(methyl styrene); and poly(styrene).

### DETAILED DESCRIPTION OF THE INVENTION

Charge carrier mobility in an organic semiconductor is dependent upon the crystallinity of the semiconductor. For example, a polycrystalline film of pentacene provides a low effective charge carrier mobility, within a range between about 0.3×10⁻⁷ cm²/Vs and about 1.5×10⁻⁵ cm²/Vs at room temperature. In contrast, where crystallization of pentacene is encouraged, as by its thermal evaporation in a vacuum or by growing a pentacene film from the vapor phase in a stream of inert gas, charge carrier mobilities within a range between about 1 cm²/Vs and about 5 cm²/Vs at room temperature can be achieved.

At a molecular level, charge carrier mobility in an organic polymer depends on the size, separation and relative energy levels of crystal grains. The size distribution of crystal grains determines how many of them must be effectively traversed by a charge carrier in order to be transported from an origin to a destination. The separation between crystal grains determines the impact of non-crystalline regions on charge-carrier mobility. For example, crystal grains separated by a distance greater than the tunneling limit for a particular material may constitute a nonconductive pathway for charge-carriers.

It has now been discovered that vapor-depositing pentacene onto films or substrates coated with a polymer such as poly(vinylpyridine) or poly(vinyinaphthalene) leads to the formation of pentacene films with large grain sizes and improved charge-carrier mobilities. Polymers that induce the growth of large grain sizes in vapor-deposited pentacene, and consequently large mobilities in the deposited pentacene, will be referred to herein as “high mobility polymers.” Vapor deposition of pentacene onto poly(vinylpyridine) or poly(vinylnaphthalene) gives pentacene domains up to 1.0 micron in diameter, as determined by atomic force micoscopy, and the resulting mobilities of the pentacene are as large as those observed for pentacene deposited on poly(hydroxy styrene).

This result is especially surprising because deposition onto poly(styrene), or a number of other poly(vinylarene) films or substrates, gives much smaller domains, usually less than 0.5 microns in diameter.

For use in the process of this invention, the high mobility polymer is generally deposited onto a substrate or coating from solution. Suitable substrates include glass and polymer substrates such as polyesters (especially PET or PEN) and polyimides.

A convenient way to deposit the high mobility polymer is to dissolve it in a suitable solvent and spin-coat it onto a substrate. For example, a 5-10 wt % solution of poly(4-vinylpyridine) in methyl ethyl ketone can be prepared and used for spin-coating onto a glass substrate to give a film of suitable thickness. Films of 1 micron thickness are acceptable for many applications. If desired, portions of the deposited high mobility polymer can be removed, for example by wiping the portions to be removed with a swab dipped in methyl ethyl ketone or other suitable solvent.

The pentacene is applied onto the high mobility polymer by vacuum sublimation. The substrate coated with the high mobility polymer and a source of pentacene are placed in a suitable vacuum chamber that is then evacuated. The source of pentacene is heated to sublimate and deposit a pentacene layer over the high mobility polymer. The high mobility polymer encourages the growth of large crystal grains in the pentacene layer, leading to pentacene with high charge-carrier mobility

### EXAMPLES

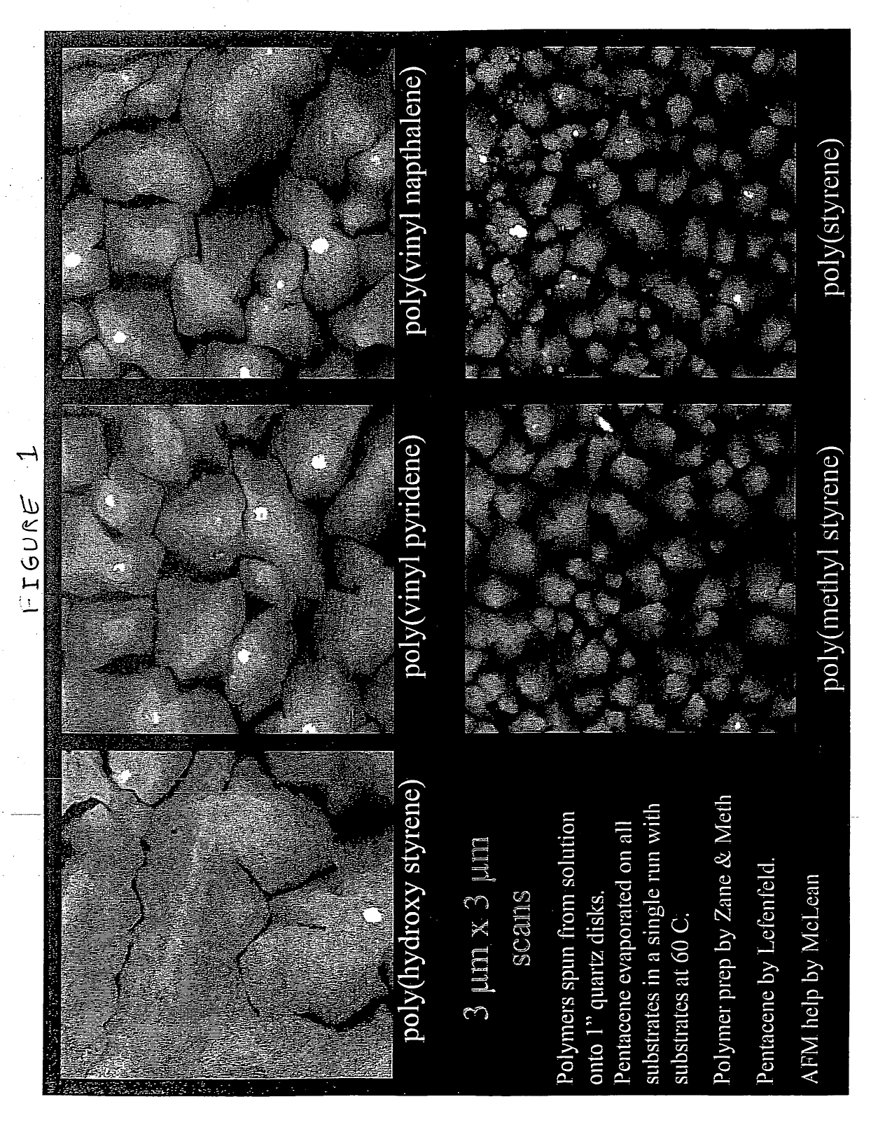

FIG. 1 provides AFM images of pentacene deposited as described above on several different types of polymers. The AFM images of pentacene on poly(vinyl pyridine) and poly(vinyl naphthalene) illustrate the large pentacene grains that can be achieved by the process of this invention.

In contrast, deposition of pentacene on poly(methyl styrene) or poly(styrene) is shown to give relatively small pentacene crystal grains.

The mobility for the pentacene samples deposited on poly(vinyl pyridine) and poly(vinylnaphthalene) are comparable to the mobilities of pentacene on poly(hydroxy styrene), and higher than the mobilities measured for pentacene deposited on poly(styrene) or poly(methyl styrene)

1. A method for forming pentacene films with high charge carrier mobilities comprising vapor-depositing pentacene onto films or substrates comprising polymers selected from the group consisting of poly(vinylpyridine) and poly(vinylnaphthalene).

2. The method of claim 1 wherein the substrate is selected from the group of materials consisting of glass and polymer.

3. The method of claim 2 wherein the substrate is selected from the group consisting of polyesters and polyimides.

4. The method of claim 3 wherein the polyester is selected from the group consisting of PET and PEN.
